(19) United States
(12) Patent Application Publication
(10) Pub. No.: US 2019/0042360 A1
(43) Pub. Date: Feb. 7, 2019

(54) ERROR CORRECTION CIRCUIT AND MEMORY SYSTEM INCLUDING THE SAME

(71) Applicant: SK hynix Inc., Gyeonggi-do (KR)

(72) Inventor: Young-Ook SONG, Seoul (KR)

(21) Appl. No.: 15/936,684

(22) Filed: Mar. 27, 2018

(30) Foreign Application Priority Data
Aug. 3, 2017 (KR) 10-2017-0098599

(51) Int. Cl. G06F 11/10; G11C 29/52; H03M 13/15

(52) U.S. Cl. CPC G06F 11/1068; G11C 29/52; H03M 13/1575; H03M 13/1545; H03M 13/153

(57) ABSTRACT

An error correction circuit includes: a syndrome calculation block suitable for generating a syndrome based on a data and an error correction code; an error location polynomial generation block suitable for generating an error location polynomial for detecting a location of an error based on the syndrome, where the number of operation stages used for generating the error location polynomial is controlled based on condition information; and a chien search block suitable for correcting an error of the data based on the error location polynomial.

### CROSS-REFERENCE TO RELATED APPLICATIONS

The present application claims priority to Korean Patent Application No. 10-2017-0098599, filed on Aug. 3, 2017, which is incorporated herein by reference in its entirety.

### BACKGROUND

### 1. Field

Exemplary embodiments of the present invention relate to an error correction circuit and a memory system including the error correction circuit.

### 2. Description of the Related Art

In the early days of the semiconductor memory industry, a number of original good dies were found on the wafers in which no defective memory cells existed in the memory chips that passed the semiconductor fabrication process. However, as the capacity of a memory device increased, it became difficult to fabricate a memory device that does not include any defective memory cells. At present, it may be said that there is no memory device that does not include any defective memory cells. To solve this problem, a method of repairing the defective memory cells with redundant memory cells in a memory device may be used.

Also, an error correction code (ECC) circuit for correcting an error in a memory system may be used to correct an error that occurs in a memory cell and an error that occurs while data are transferred during read and write operations in the memory system.

### SUMMARY

Embodiments of the present invention are directed to a technology capable of increasing error correction efficiency in a memory system.

In accordance with an embodiment of the present invention, an error correction circuit includes: a syndrome calculation block suitable for generating a syndrome based on a data and an error correction code; an error location polynomial generation block suitable for generating an error location polynomial for detecting one or more locations of one or more errors based on the syndrome, where a number of operation stages used for generating the error location polynomial is controlled based on a condition information; and a chien search block suitable for correcting one or more errors of the data based on the error location polynomial.

In accordance with another embodiment of the present invention, a memory system includes: one or more memories suitable for storing a data and an error correction code; an error correction code (ECC) generation circuit suitable for generating the error correction code to be programmed in the one or more memories based on the data to be programmed in the one or more memories; a condition information generation circuit suitable for generating condition information that represents a probability for occurrence of an error of the one or more memories; and an error correction circuit suitable for correcting one or more errors of a data that is read from the one or more memories based on the error correction code that is read from the one or more memories, where an error correction intensity is controlled based on the condition information.

### BRIEF DESCRIPTION OF THE DRAWINGS

FIG. 1 is a block diagram illustrating a memory system in accordance with an embodiment of the present invention.

FIG. 2 is a block diagram illustrating an error correction circuit shown in FIG. 1.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The terminology used herein is for the purpose of describing particular embodiments only and is not intended to be limiting of the present invention.

Hereinafter, the various embodiments of the present invention will be described in detail with reference to the attached drawings.

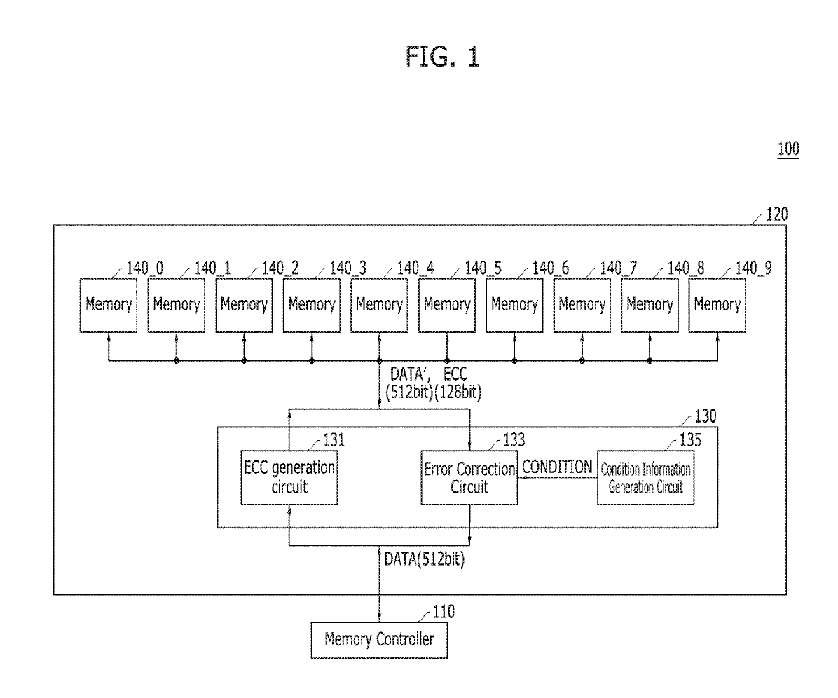

FIG. 1 is a block diagram illustrating a memory system 100 in accordance with an embodiment of the present invention. For illustrative purposes and convenience in description, FIG. 1 shows only a portion that is directly related to the transfer of data in the memory system 100.

Referring to FIG. 1, the memory system 100 may include a memory controller 110 and a memory module 120.

The memory controller 110 may control a read operation and a write operation of the memory module 120 upon a request transferred from a host (not shown). During the write operation, a data DATA may be transferred from the memory controller 110 to the memory module 120, and during the read operation, a data DATA may be transferred from the memory module 120 to the memory controller 110. In most memory systems, the unit of the data processed may be 512 bits. In other words, a read data DATA of 512 bits may be transferred from the memory module 120 to the memory controller 110 during a single read operation, and a write data DATA of 512 bits may be transferred from the memory controller 110 to the memory module 120 during a single write operation. In the figure, “512 bits” may represent the unit of the data. The memory controller 110 may be included in a processor, such as a Central Processing Unit (CPU), a Graphic Processing Unit (GPU), and an Application Processor (AP). Although FIG. 1 shows the memory controller 200 included in the memory system 100, it is for illustrative purposes only, and the memory controller 200 may be provided separately.

The memory module 120 may include a module controller 130 and memories 140_0 to 140_9. The memory module 120 may be of a Dual In-Line Memory Module (DIMM) type.

A command (not shown) and an address (not shown) may be transferred to the memories 140_0 to 140_9 through the module controller 130. While the command and the address are transferred through the module controller 130, the module controller 130 may control the transfer timing and format of the command and the address. Also, transfer and reception of a data DATA between the memory controller 110 and the memories 140_0 to 140_9 may be performed through the module controller 130. The module controller 130 may include an ECC generation circuit 131, an error correction circuit 133, and a condition information generation circuit 135 that are related to an operation of correcting an error of a data DATA′ which is stored in the memories 140_0 to 140_9.

The ECC generation circuit 131 may generate an error correction code ECC based on the data DATA transferred from the memory controller 110 during a write operation. The error correction code ECC may be a Reed Solomon (RS) code. The ECC generation circuit 131 may generate an error correction code ECC of 128 bits to correct an error that may occur in the 512-bit data DATA′. Although the number of bits of the error correction code ECC is 128 bits in FIG. 1, it will be obvious to those skilled in the art that this is a mere example and that the number of bits of the error correction code ECC may be more or less than 128 bits. In the figure, the data DATA′ may represent a data that is transferred/received between the module controller 130 and the memories 140_0 to 140_9. During a write operation, the error correction code ECC may be generated, but the operation of correcting an error of the data may not be performed. Therefore, during the write operation, the data DATA may be the same as the data DATA′.

The error correction circuit 133 may correct an error of the data DATA′ that is read from the memories 140_0 to 140_9 using the error correction code ECC, which is read from the memories 140_0 to 140_9 during a read operation. During the read operation, the data DATA whose error is corrected by the error correction circuit 133 may be transferred to the memory controller 110.

The intensity of the error correction operation of the error correction circuit 133 may be controlled based on condition information CONDITION. When the condition information CONDITION indicates that an error is likely to occur in the memories 140_0 to 140_9, the error correction circuit 133 may increase the intensity of the error correction operation. When the condition information CONDITION indicates that the probability for occurrence of an error in the memories 140_0 to 140_9 is low, the error correction circuit 133 may lower the intensity of the error correction operation. When the intensity of the error correction operation of the error correction circuit 133 is set high, the error correction circuit 133 may correct a large number of errors, but may require more time to perform the error correction operation. In contrast, when the intensity of the error correction operation of the error correction circuit 133 is set low, the error correction circuit 133 may correct a small number of errors, but may require less time to perform the error correction operation. To summarize, the higher the intensity of the error correction operation of the error correction circuit 133 is, the more errors may be corrected while requiring more time to perform the error correction operation.

The condition information generation circuit 135 may generate the condition information CONDITION that may indicate the probability of an error occurring in the memories 140_0 to 140_9. The condition information CONDITION may include a one-bit signal or multi-bit signals. As the number of bits of the condition information CONDITION is higher, the accuracy of the condition information CONDITION may increase. For example, when the condition information CONDITION is one-bit, the condition information CONDITION may only indicate the probability of an error occurring as high and low. However, when the condition information CONDITION is two-bits, the condition information CONDITION may indicate the probability of an error occurring as very high, high, low and very low. The condition information generation circuit 135 may generate the condition information CONDITION based on at least one information among (1) the temperature of the memories 140_0 to 140_9, (2) refresh cycle of the memories 140_0 to 140_9, (3) error log records of the memories 140_0 to 140_9, (4) speed of the memories 140_0 to 140_9, and (5) voltage level of the memories 140_0 to 140_9.

The condition information CONDITION may be generated based on the temperature of the memories 140_0 to 140_9.

When the temperature of the memories 140_0 to 140_9 increases, the probability of losing the stored data may increase. The condition information generation circuit 135 may generate the condition information CONDITION indicating that the probability an error occurring is high as the temperature of the memories 140_0 to 140_9 becomes high. Each of the memories 140_0 to 140_9 may include a thermo-sensor inside. The condition information generation circuit 135 may generate the condition information CONDITION by reading temperature information sensed by the thermo-sensor of the memories 140_0 to 140_9. The condition information generation circuit 135 may read the temperature information from all the thermo-sensors of the memories 140_0 to 140_9. However, since the memories 140_0 to 140_9 are likely to have almost the same temperature, the condition information generation circuit 135 may generate the condition information CONDITION by reading temperature information from the thermo-sensor of one among the memories 140_0 to 140_9.

The condition information CONDITION may be generated based on the refresh cycle of the memories 140_0 to 140_9.

When the memories 140_0 to 140_9 perform a refresh operation frequently, there is an increased probability that the data of the memories 140_0 to 140_9 will not be lost. On the other hand, when the memories 140_0 to 140_9 perform a refresh operation less frequently, there is an increased probability that the data of the memories 140_0 to 140_9 will be lost. Thus, the condition information generation circuit 135 may generate the condition information CONDITION indicating that the probability of an error occurring is high as the memories 140_0 to 140_9 perform the refresh operation less frequently. On the other hand, the condition information generation circuit 135 may generate the condition information CONDITION indicating that the probability of an error occurring is low as the memories 140_0 to 140_9 perform the refresh operation more frequently. A refresh command applied to the memories 140_0 to 140_9 may be delivered to the memories 140_0 to 140_9 through the module controller 130. The condition information generation circuit 135 may determine whether the refresh operation is performed frequently or less frequently in the memories 140_0 to 140_9 by monitoring the refresh command that is transferred to the memories 140_0 to 140_9. The condition information generation circuit 135 may generate the condition information CONDITION based on the result of the determination.

The condition information CONDITION may be generated based on the error log records of the memories 140_0 to 140_9.

The condition information generation circuit 135 may generate an error log by storing error occurring history whenever the error correction circuit 133 detects an error, and generate the condition information CONDITION based on the error log. For example, the condition information generation circuit 135 may generate the condition information CONDITION differently for a case where the number of errors occurred in the last 100 times of read operations ranges from 0 to 30, a case where the number of errors occurred in the last 100 times of read operations ranges from 31 to 60, a case where the number of errors occurred in the last 100 times of read operations ranges from 61 to 90, and a case where the number of errors occurred in the last 100 times of read operations is more than 91.

The condition information CONDITION may be generated based on the speed of the memories 140_0 to 140_9.

When the memories 140_0 to 140_9 operate at high speeds, more errors are likely to occur, compared to when the memories 140_0 to 140_9 operate at relatively low speeds. The condition information generation circuit 135 may generate the condition information CONDITION by detecting operation frequency of the memories 140_0 to 140_9. The condition information generation circuit 135 may include a frequency detector for detecting the frequency of a clock that is transferred to the memories 140_0 to 140_9, and it may generate the condition information CONDITION based on the detection result of the frequency detector.

The condition information CONDITION may be generated based on the voltage level of the memories 140_0 to 140_9.

Since the memories 140_0 to 140_9 operate more stably when the operation voltage of the memories 140_0 to 140_9 is high, compared to when the operation voltage of the memories 140_0 to 140_9 is low, the condition information generation circuit 135 may generate the condition information CONDITION based on the voltage level of the memories 1400 to 1409. The condition information generation circuit 135 may include a voltage detector for detecting the level of the power source voltage that is applied to the memories 140_0 to 140_9, and generate the condition information CONDITION based on the detection result of the voltage detector.

The memories 140_0 to 140_9 may be one among the various kinds of memories, such as a Dynamic Random Access Memory (DRAM), a Phase Change Random Access Memory (PCRAM), and a flash memory. Each of the memories 140_0 to 140_9 may store a 64-bit data during a single write operation, and output a 64-bit data during a single read operation. Since a total of 640 bits of data may be inputted/outputted to/from the 10 memories 140_0 to 140_9 during each write operation and each read operation, a 512-bit data DATA′ and a 128-bit error correction code ECC may be programmed in or read from the memories 140_0 to 140_9.

Although FIG. 1 shows an example that the ECC generation circuit 131, the error correction circuit 133, and the condition information generation circuit 135 are included in the module controller 130, it is to be noted that the present invention is not limited thereto. That is, the ECC generation circuit 131, the error correction circuit 133, and the condition generation circuit 135 may be included in the memory controller 110, or they may be separately provided from the module controller 130. In short, the ECC generation circuit 131, the error correction circuit 133, and the condition information generation circuit 135 may be independently provided in the memory system 100.

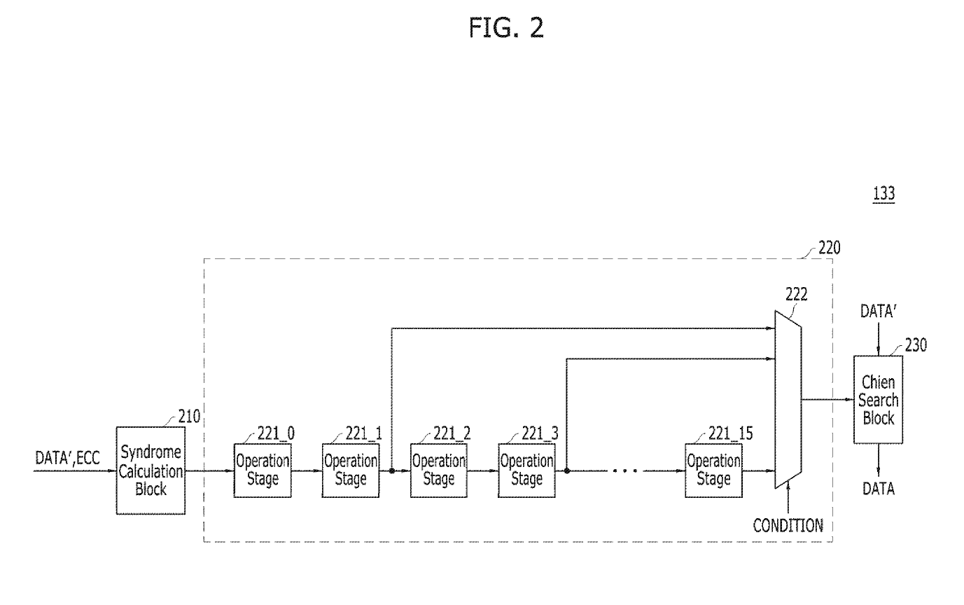

FIG. 2 is a block diagram illustrating an error correction circuit 133 shown in FIG. 1.

Referring to FIG. 2, the error correction circuit 133 may include a syndrome calculation block 210, an error location polynomial generation block 220, and a chien search block 230.

The syndrome calculation block 210 may generate a syndrome based on the error correction code ECC and the data DATA′ that are read from the memories 140_0 to 140_9. The syndrome may be generated as a result of XOR and AND operations between a particular matrix and a code word. Herein, the code word may represent the data DATA′ and the error correction code ECC.

The error location polynomial generation block 220 may generate an error location polynomial based on the syndrome generated in the syndrome calculation block 210. The error location polynomial may be generated by repeatedly performing an operation using a Berlekamp-Massey (BM) algorithm through a plurality of operation stages 221_0 to 221_15. The operation stages 221_0 to 221_15 may be coupled in series to repeatedly perform the operation using the BM algorithm. The error correction performance of the error correction circuit 133 may depend on how many times the operation using the BM algorithm is performed. For example, when one symbol includes 8 bits, and the data DATA′ includes 64 symbols (=512 bits), and the error correction code ECC includes 16 symbols (=128 bits) in an RS code, the error correction circuit 133 may correct an error of 8 symbols by performing the operation using the BM algorithm 16 times, correct an error of 6 symbols by performing the operation using the BM algorithm 12 times, and correct an error of 4 symbols by performing the operation using the BM algorithm 8 times.

The error location polynomial generation block 220 may include a selector 222 for selecting one among the outputs of the operation stages 221_1, 221_3, 221_5 to 221_13, and 221_15 according to the condition information CONDITION and transfer the selected output to the chien search block 230. The operation stages 221_0 to 221_15 may be coupled series and perform the operation using the BM algorithm. The selector 222 may select later-staged one among outputs of the operation stages 221_1, 221_3, 221_5 to 221_13, and 221_15 when the condition information CONDITION indicates higher probability of an error occurring, and transfer the selected output to the chien search block 230. When the selector 222 selects later-staged one among outputs of the operation stages 221_1, 221_3, 221_5 to 221_13, and 221_15, the error correction capability and the time required for the error correction may increase. In contrast, when the selector 222 selects earlier-staged one among outputs of the operation stages 221_1, 221_3, 221_5 to 221_13, and 221_15, the error correction capability and the time taken for the error correction may decrease.

The chien search block 230 may calculate the value of the error location polynomial that is generated in the error location polynomial generation block 220 to correct an error of the data DATA′ and generate the data DATA whose error is corrected.

According to the embodiments of the present invention, error correction efficiency of a memory system may be increased.

While the present invention has been described with respect to the specific embodiments, it will be apparent to those skilled in the art that various changes and modifications may be made without departing from the spirit and scope of the invention as defined in the following claims.

What is claimed is:

1. An error correction circuit, comprising:
a syndrome calculation block suitable for generating a syndrome based on a data and an error correction code;
an error location polynomial generation block suitable for generating an error location polynomial for detecting one or more locations of one or more errors based on the syndrome, where a number of operation stages used for generating the error location polynomial is controlled based on a condition information; and
a chien search block suitable for correcting one or more errors of the data based on the error location polynomial.

2. The error correction circuit of claim 1, wherein the number of operation stages used for generating the error location polynomial is greater when the condition information indicates that a probability of an error occurring is high than when the condition information indicates that a probability of an error occurring is low.

3. The error correction circuit of claim 1, wherein the error location polynomial generation block includes:
a plurality of operation stages for sequentially performing an operation using a Berlekamp-Massey (BM) algorithm; and
a selector suitable for selecting one among outputs of the operation stages based on the condition information and transferring the selected output to the chien search block.

4. The error correction circuit of claim 1, wherein the condition information includes at least one among a temperature of a memory storing the data, a refresh cycle of the memory storing the data, an error log record of the memory storing the data, speed information of the memory storing the data, and voltage level information of the memory storing the data.

5. The error correction circuit of claim 4, wherein the condition information generation circuit generates the condition information by reading temperature of a thermometer inside the memory.

6. The error correction circuit of claim 4, wherein the condition information generation circuit generates the condition information by monitoring a refresh command transferred to the memory.

7. The error correction circuit of claim 4, wherein the condition information generation circuit stores a history of errors detected by the error correction circuit and generates the condition information based on the stored history of the errors.

8. The error correction circuit of claim 4, wherein the condition information generation circuit includes a frequency detector for detecting a frequency of a clock that is transferred to the memory, and generates the condition information based on a detection result of the frequency detector.

9. The error correction circuit of claim 4, wherein the condition information generation circuit includes a voltage detector for detecting a level of a power source voltage and generates the condition information based on a detection result of the voltage detector.

10. The error correction circuit of claim 3, wherein the operation stages are coupled in series to repeatedly perform the operation using the BM algorithm.

11. A memory system, comprising:
one or more memories suitable for storing a data and an error correction code;
an error correction code (ECC) generation circuit suitable for generating the error correction code to be programmed in the one or more memories based on the data to be programmed in the one or more memories;
a condition information generation circuit suitable for generating condition information that indicates a probability an error occurring in the one or more memories; and
an error correction circuit suitable for correcting one or more errors of a data that is read from the one or more memories based on the error correction code that is read from the one or more memories, where an error correction intensity is controlled based on the condition information.

12. The memory system of claim 11, wherein the error correction circuit includes:
a syndrome calculation block suitable for generating a syndrome based on the data that is read from the one or more memories and the error correction code that is read from the one or more memories;
an error location polynomial generation block suitable for generating an error location polynomial for detecting one or more locations of one or more errors based on the syndrome, where the number of operation stages used for generating the error location polynomial is controlled based on condition information; and
a chien search block suitable for correcting one or more errors of the data that is read from the one or more memories based on the error location polynomial.

13. The memory system of claim 12, wherein the number of the operation stages used for generating the error location polynomial is greater when the condition information indicates that a probability of an error occurring is high than when the condition information indicates that a probability of an error occurring is low.

14. The memory system of claim 12, wherein the error location polynomial generation block includes:
a plurality of the operation stages for sequentially performing an operation using a Berlekamp-Massey (BM) algorithm; and
a selector suitable for selecting one among outputs of the operation stages based on the condition information and transferring the selected output to the chien search block.

15. The memory system of claim 11, wherein the condition information includes at least one among a temperature of the one or more memories, a refresh cycle of the one or more memories, an error log record of the one or more memories, speed information of the one or more memories, and voltage level information of the one or more memories.

16. The memory system of claim 11, wherein the one or more memories, the ECC generation circuit, the condition information generation circuit, and the error correction circuit are included in a memory module.

17. The memory system of claim 16, wherein the ECC generation circuit, the condition information generation circuit, and the error correction circuit are included in a module controller of the memory module.

18. The memory system of claim 17, wherein the memory system further includes:
a memory controller suitable for controlling the memory module.
